(19) United States
(12) Patent Application Publication
(10) Pub. No.: US 2024/0021733 A1
(43) Pub. Date: Jan. 18, 2024

(54) STACKED SEMICONDUCTOR DEVICE

(71) Applicant: INTERNATIONAL BUSINESS MACHINES CORPORATION, ARMONK, NY (US)

(72) Inventors: Kangguo Cheng, Schenectady, NY (US); Julien Frougier, Albany, NY (US); Ruilong Xie, Niskayuna, NY (US); Chanro Park, Clifton Park, NY (US)

(21) Appl. No.: 17/813,136

(22) Filed: Jul. 18, 2022

(51) Int. Cl. H01L 29/786; H01L 29/66; H01L 29/78; H01L 21/8234; H01L 21/84; H01L 21/02

(52) U.S. Cl. CPC H01L 29/78696; H01L 29/66803; H01L 29/785; H01L 21/823431; H01L 21/845; H01L 21/02595

(57) ABSTRACT

A stacked semiconductor device includes stacked transistors. A lower transistor may be a p-type FinFET and an upper transistor vertically above the lower transistor may be a n-type nanostructure FET. The lower transistor may include a fin channel with a (110) orientated crystalline side surface. End surfaces of the fin channel contact a respective lower source/drain (S/D) region. The (110) orientated crystalline side surface may contact a lower gate structure. The upper transistor includes a diamond-shaped nano channel with a (111) orientated crystalline perimeter surface. End surfaces of the diamond-shaped nano channel may contact a respective upper S/D region. An upper gate structure may wrap around and contact the (111) orientated crystalline perimeter surface. An electrical isolation structure may separate the upper transistor from the lower transistor.

### BACKGROUND

Various embodiments of the present application generally relate to semiconductor device fabrication operations and resulting devices. More specifically the various embodiments relate to a stacked semiconductor device.

### SUMMARY

In an embodiment of the present invention, a stacked semiconductor device is presented. The stacked semiconductor device includes a lower transistor and upper transistor. The lower transistor includes a fin channel, a lower source/drain (S/D) region that contacts an end surface of the fin channel, and a lower gate structure that contacts a sidewall of the fin channel. The upper transistor is stacked vertically above the lower transistor and includes a diamond-shaped nano channel, an upper S/D region that contacts an end surface of the diamond-shaped nano channel, and an upper gate structure that wraps around and contacts the diamond-shaped nano channel.

In an embodiment of the present invention, another stacked semiconductor device is presented. The stacked semiconductor device includes a lower transistor and upper transistor. The lower transistor includes a fin channel, a lower source that contacts an end surface of the fin channel, a lower drain that contacts a distal end surface of the fin channel, and lower gate that contacts a sidewall of the fin channel. The upper transistor is stacked vertically above the lower transistor and includes a diamond-shaped nano channel, an upper source that contacts an end surface of the diamond-shaped nano channel, an upper drain that contacts a distal end surface of the diamond-shaped nano channel, and an upper gate that wraps around and contacts a perimeter of the diamond-shaped nano channel.

In another embodiment of the present invention, a stacked semiconductor device fabrication method is presented. The fabrication method includes forming a fin channel of a lower transistor. The fabrication method includes forming a lower gate structure, of the lower transistor, upon a sidewall of the fin channel. The fabrication method includes forming a diamond-shaped channel of an upper transistor that is vertically stacked above the lower transistor. The fabrication method includes forming an upper gate structure, of the upper transistor, upon and around the diamond-shaped channel.

These and other embodiments, features, aspects, and advantages will become better understood with reference to the following description, appended claims, and accompanying drawings.

### BRIEF DESCRIPTION OF THE DRAWINGS

FIG. 1 through FIG. 14 depicts cross-sectional views of a stacked semiconductor device shown after fabrication operation(s), in accordance with one or more embodiments.

FIG. 15 is a flow diagram illustrating a semiconductor device fabrication method, in accordance with one or more embodiments.

### DETAILED DESCRIPTION

Stacked semiconductor devices have emerged as a viable option for extending semiconductor device scaling. There are a variety of transistor types utilized in known stacked semiconductor devices, with each transistor type, such as Fin Field Effect transistors (FET), nanosheet, nanowire, and the like, having unique implementation challenges. The embodiments therefore provide for a stacked semiconductor device that includes performance benefits for stacked nFETs and pFETs. In a particular implementation, a pFET includes a (110) planar fin channel and is vertically below a nFET that includes a (111) planar diamond-shaped nano channel.

Although this detailed description includes examples of how aspects of the invention can be implemented to form an exemplary stacked semiconductor device, implementation of the teachings recited herein are not limited to a particular type of FET structure or combination of materials. Rather, embodiments of the present invention are capable of being implemented in conjunction with any other type of transistor device or material, now known or later developed, wherein it is desirable to provide an increased source/drain contact area and a reduced distance between the source/drain contact and the channel.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. Various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to a description of technologies that are more specifically relevant to the present invention, transistors are semiconductor devices commonly found in a wide variety of ICs. A transistor is essentially a switch. When a voltage is applied to a gate of the transistor that is greater than a threshold voltage, the switch is turned on, and current flows through the transistor. When the voltage at the gate is less than the threshold voltage, the switch is off, and current does not flow through the transistor.

Typical semiconductor devices are formed using active regions of a wafer. The active regions are defined by isolation regions used to separate and electrically isolate adjacent semiconductor devices. For example, in an IC having a plurality of metal oxide semiconductor MOSFETs, each MOSFET has a source and a drain that are formed in an active region of a semiconductor layer by implanting n-type or p-type impurities in the layer of semiconductor material. Disposed between the source and the drain is a channel (or body) region. Disposed above the body region is a gate electrode. The gate electrode and the body are spaced apart by a gate dielectric layer.

MOSFET-based ICs are fabricated using so-called complementary metal oxide semiconductor (CMOS) fabrication technologies. In general, CMOS is a technology that uses complementary and symmetrical pairs of p-type and n-type MOSFETs to implement logic functions. The channel region connects the source and the drain, and electrical current flows through the channel region from the source to the drain. The electrical current flow is induced in the channel region by a voltage applied at the gate electrode.

A fin field-effect transistor (FinFET) is a MOSFET and is typically built on a substrate where the gate is placed on three sides of the fin channel. These devices have been referred to as FinFETs because the at least a channel region forms fins on the silicon surface. It is common for a single FinFET transistor to contain several fins, arranged side by side and all covered by the same gate, that act electrically as one, to increase drive strength and performance.

The wafer footprint of a FET is related to the electrical conductivity of the channel material. If the channel material has a relatively high conductivity, the FET can be made with a correspondingly smaller wafer footprint. A known method of increasing channel conductivity and decreasing FET size is to form the channel as a nanostructure. For example, a so-called gate-all-around (GAA) FET is a known architecture for providing a relatively small FET footprint by forming the channel region as a series of nano structures. In a known GAA configuration, a nanostructure-based FET includes a source region, a drain region, and stacked nanostructure channels between the source and drain regions. A gate surrounds the stacked nanostructure channels and regulates electron flow through the nanostructure channels between the source and drain regions. GAA nanostructure FETs are fabricated by forming alternating layers of channel nanostructure and sacrificial nanostructure layers. The sacrificial nanostructure layers are released from the channel nanostructures before the FET device is finalized. For n-type FETs, the channel nanostructure layers are typically silicon (Si) and the sacrificial nanostructure layers are typically silicon germanium (SiGe). For p-type FETs, the channel nanostructure layers can be SiGe and the sacrificial nanostructure layers can be Si. In some implementations, the channel nanostructure of a p-type FET can be SiGe or Si, and the sacrificial nanostructure can be Si or SiGe. Forming the GAA nanostructures from alternating layers of channel nanostructure layers formed from a first type of semiconductor material (e.g., Si for n-type FETs, and SiGe for p-type FETs) and sacrificial nanostructure layers formed from a second type of semiconductor material (e.g., SiGe for n-type FETs, and Si for p-type FETs) provides superior channel electrostatics control, which is necessary for continuously scaling of CMOS technology. The use of different channel materials for PFET vs. NFET is typically to improve channel mobility, and resultant overall device performance.

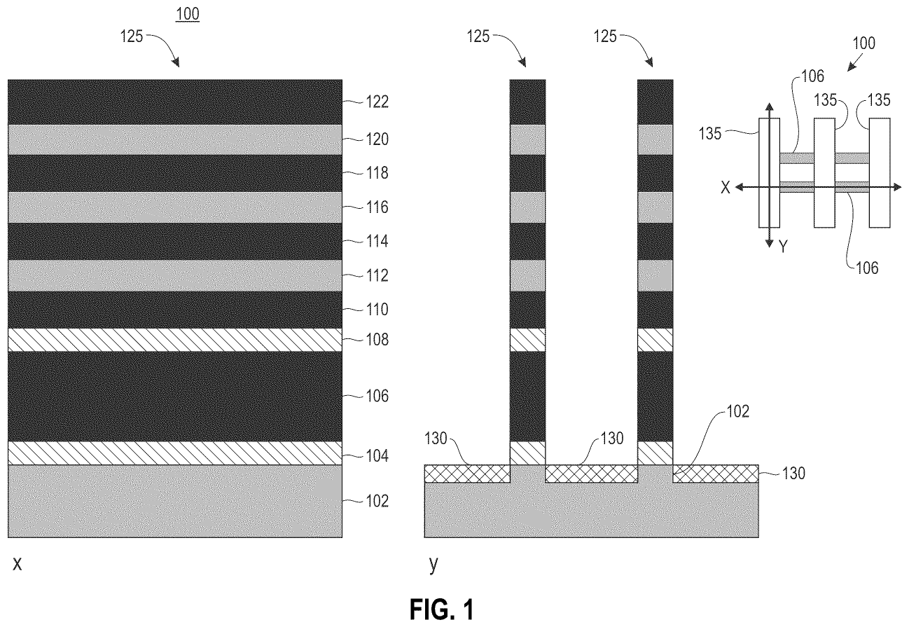

Turning now to a more detailed description of fabrication operations and resulting structures according to aspects of the invention, FIGS. 1-14 depict a stacked semiconductor device 100 after various fabrication operations. For ease of illustration, the fabrication operations depicted in FIGS. 1-14 will be described in the context of forming a n-type GAA nanostructure vertically above a p-type finFET. The fabrication operations described herein apply equally to the fabrication of any number and/or logical positioning of various FET types.

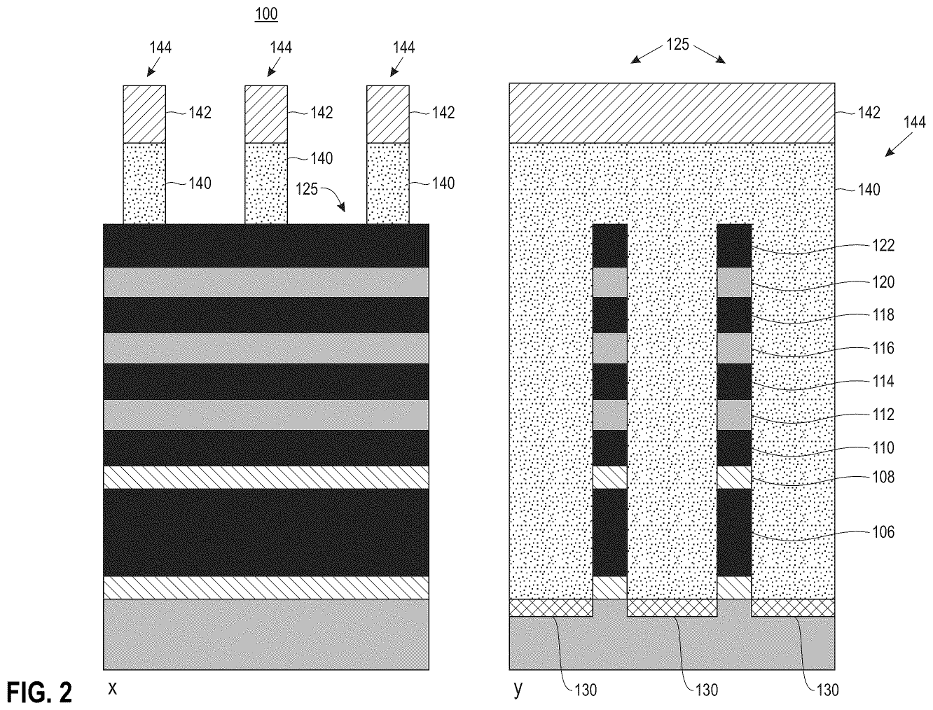

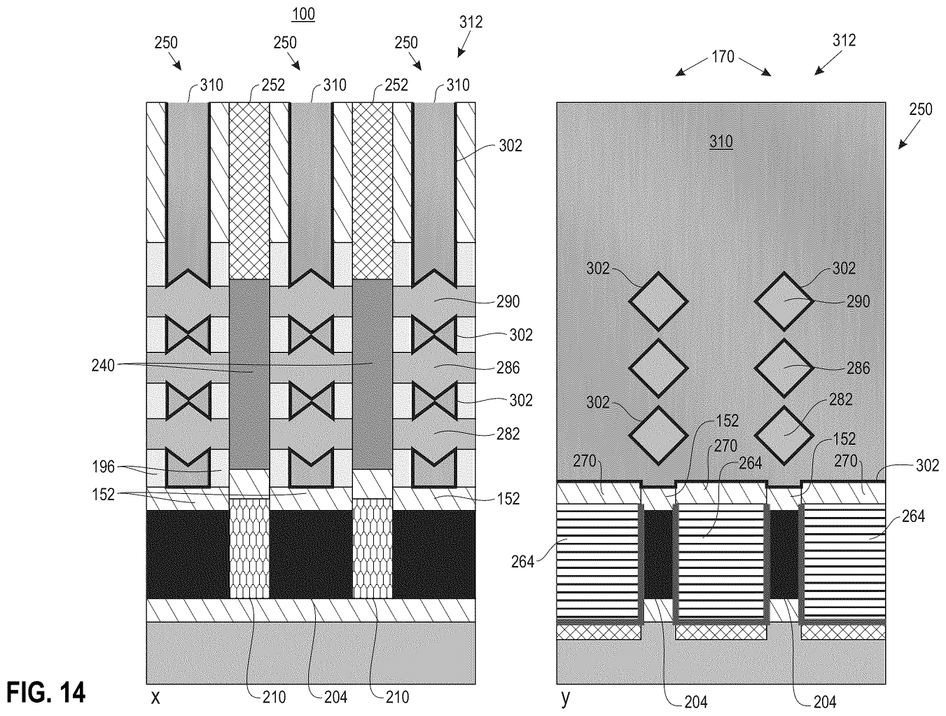

Although the cross-sectional diagrams depicted in FIGS. 1-14 are two-dimensional, it is understood that the diagrams depicted in FIGS. 1-14 represent three-dimensional devices. The top-down reference diagram shown in FIG. 1 provides a reference point for the various cross-sectional views (X-view, Y-view) shown in FIGS. 1-14. The X-view is a side cross-sectional view taken along a channel fin 106 across three gates 135, the Y-view is another side cross-sectional view taken along a gate 135 across two channel fins 106. For clarity, gate 135 is depicted as a generic gate or gate structure and may be, for example, a sacrificial gate 140 or sacrificial gate structure 144, shown in FIG. 2, a replacement gate conductor 310 or replacement gate structure 312, shown in FIG. 14, or the like.

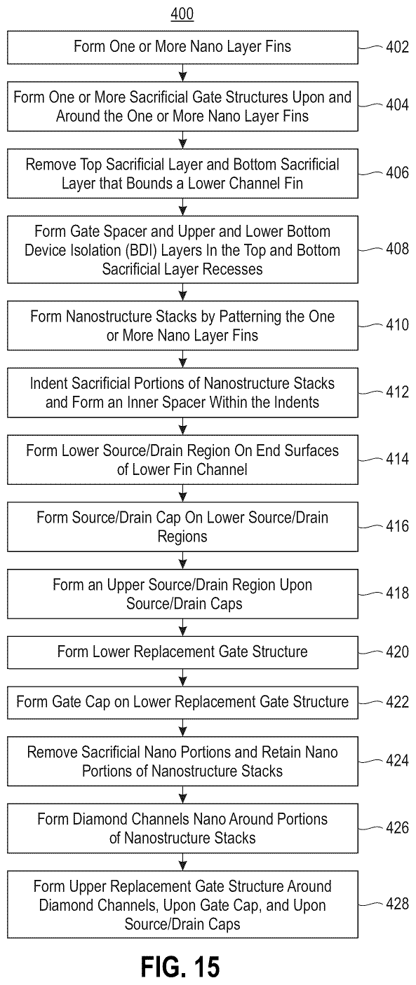

FIG. 1 depicts cross-sectional views of the stacked semiconductor device 100 after initial fabrication operations in accordance with aspects of the present embodiments. In the present fabrication stage, as shown in block 402 of a method 400 of fabricating semiconductor device 100 of FIG. 15, one or more nanolayer fins 125 are formed upon a substrate 102. Further in the present fabrication stage, shallow trench isolation (STI) region(s) 130 may be formed upon the substrate 102 next to the fins 125.

Non-limiting examples of suitable materials for the substrate 102 include Si (silicon), strained Si, SiC (silicon carbide), Ge (germanium), SiGe (silicon germanium), SiGe:C (silicon-germanium-carbon), Si alloys, Ge alloys, III-V materials (e.g., GaAs (gallium arsenide), InAs (indium arsenide), InP (indium phosphide), or aluminum arsenide (AlAs)), II-VI materials (e.g., CdSe (cadmium selenide), CdS (cadmium sulfide), CdTe (cadmium telluride), ZnO (zinc oxide), ZnSe (zinc selenide), ZnS (zinc sulfide), or ZnTe (zinc telluride)), or any combination thereof. Other non-limiting examples of semiconductor materials include III-V materials, for example, indium phosphide (InP), gallium arsenide (GaAs), aluminum arsenide (AlAs), or any combination thereof. The III-V materials can include at least one “III element,” such as aluminum (Al), boron (B), gallium (Ga), indium (In), and at least one “V element,” such as nitrogen (N), phosphorous (P), arsenic (As), antimony (Sb). The substrate 102 can be a bulk semiconductor material that includes Si.

A bottom set of finFET layers, such as a bottom sacrificial layer, a channel fin layer, and top sacrificial layer, may be formed upon substrate 102. Subsequently, alternating nanostructure layers may be formed upon the bottom set of finFET layers.

The bottom sacrificial layer, of which bottom sacrificial portion 104 of each fin 125 may be formed therefrom, may be formed over substrate 102. The bottom sacrificial layer may comprise an epitaxial SiGe layer with high Ge %, ranging from 50% to 70%. The channel fin layer, of which channel fin 106 of each fin 125 may be formed therefrom, may be formed over bottom sacrificial layer. The channel fin layer may comprise an epitaxial SiGe layer with lower Ge %, ranging from 20% to 45%. The top sacrificial layer, of which sacrificial portion 108 of each fin 125 may be formed therefrom, may be formed over the channel fin layer. The top sacrificial layer may comprise an epitaxial SiGe layer with high Ge %, ranging from 50% to 70%.

The bottom sacrificial layer and top sacrificial layer can have a thickness of, for example, from about 4 to about 15 nm. The channel fin layer can have a thickness of, for example, from about 4 to about 15 nm.

The nanolayer stack may include an alternating series of sacrificial nanolayers, such as SiGe sacrificial nanolayers, and nanolayers, such as Si nanolayers. The sacrificial SiGe nanolayers could have lower Ge % ranging from 20% to 45%. Sacrificial portions 110, 114, 118, and 122 of each fin 125 may be formed from an associated sacrificial nanolayer and nanostructure channels 112, 116, and 120 of each fin 125 may be formed from an associated nanolayer.

In accordance with aspects of the invention, the bottom sacrificial layer may be epitaxially grown from the substrate 102, the channel fin layer may be epitaxially grown from the bottom sacrificial layer, the top sacrificial layer may be epitaxially grown from the channel fin layer, and the alternating nanolayers of the nanolayer stack may be epitaxially grown from the underlying layer.

The alternating layers may be formed by epitaxially growing one layer and then the next until the desired number and desired thicknesses of the layers are achieved. Any number of alternating layers can be provided. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process. Epitaxial silicon, silicon germanium, and/or carbon doped silicon (Si:C) silicon can be doped during deposition (in-situ doped) by adding dopants, n-type dopants (e.g., phosphorus or arsenic) or p-type dopants (e.g., boron or gallium), depending on the type of transistor.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

In some embodiments of the invention, the bottom sacrificial layer and top bottom sacrificial layer is SiGe having a Ge percentage that is sufficiently different from the Ge percentage in the sacrificial nanolayers and the channel fin layer, such that the bottom sacrificial layer and top sacrificial layer can be selectively removed without also removing the SiGe sacrificial nanolayers and the channel fin layer.

In some embodiments of the invention, the nanolayers are formed from silicon (Si) and can include, for example, monocrystalline Si. The nanolayers can have a thickness of, for example, from about 4 to about 12 nm. In embodiments where the sacrificial nanolayers include SiGe, the sacrificial nanolayers can have a thickness of, for example, from about 4 to about 12 nm.

In some embodiments, the alternating series of sacrificial nanolayers with one nanolayer are formed by epitaxially growing one layer and then the next until the desired number and desired thicknesses of such layers are achieved. Subsequently, a mask layer (not shown) may be formed upon the top of the sacrificial nanolayer.

One or more fins 125 that consist of the bottom sacrificial portion 104, the channel fin 106, the top sacrificial portion 108, the sacrificial nanolayer portion 110, the nanostructure channel 112, the sacrificial nanolayer portion 114, the nanostructure channel 116, the sacrificial nanolayer portion 118, the nanostructure channel 120, and the sacrificial nanolayer portion 122 may be formed by patterning the associated layers, or portions thereof. Subsequently, STI regions 130 may be formed over the substrate 102 and adjacent to the one or more fins 125. In the embodiment depicted, a top surface of one or more STI regions 130 may be coplanar with a bottom surface of bottom sacrificial portion(s) 104 of one or more fins 125.

The one or more fins 125 may be patterned by removing respective undesired portion(s) or section(s) of the aforementioned layers while retaining respective desired portions. The removal of undesired portions of the bottom sacrificial layer, channel fin layer, top sacrificial layer, and the alternating sacrificial nanolayers and nanolayers can be accomplished using, for example, conventional lithography and etch process. The removal of such undesired portions may further remove undesired portions of substrate 102, as depicted.

Desired portions of bottom sacrificial layer, channel fin layer, top sacrificial layer, and the alternating sacrificial nanolayers and nanolayers may be retained, thereby forming the one or more fins 125.

STI regions 130 may be formed by depositing STI dielectric material upon the substrate 102 and adjacent to the fins 125, followed by STI dielectric material chemical mechanical polish (CMP), etch back, recess, or the like. STI regions 130 may electrically isolate components or features of neighboring FETs, or the like, as is known in the art.

FIG. 2 depicts cross-sectional views of stacked semiconductor device 100 shown after exemplary fabrication operation(s), in accordance with one or more embodiments. In the depicted fabrication stage, as shown in block 404 of method 400 of fabricating semiconductor device 100 of FIG. 15, one or more sacrificial gate structures 144 are formed upon and around the one or more fins 125 and upon STI regions 130. Sacrificial gate structure 144 may include a sacrificial gate liner (not shown), a sacrificial gate 140, and a sacrificial gate cap 142.

The sacrificial gate structure 144 may be formed by initially forming a sacrificial gate liner layer (e.g., a dielectric, oxide, or the like) upon substrate STI regions 130 and upon and around fins 125. For instance, the sacrificial gate liner layer may be deposited upon the upper surface of STI regions 130, sidewalls of channel fin 106, sidewalls of top sacrificial portion 108, sidewalls of sacrificial nanolayer portion 110, sidewalls of nanostructure channel 112, sidewalls of sacrificial nanolayer portion 114, sidewalls of nanostructure channel 116, sidewalls of sacrificial nanolayer portion 118, sidewalls of nanostructure channel 120, and sidewalls and upper surface of sacrificial nanolayer portion 122.

The sacrificial gate structure 144 may further be formed by subsequently forming a sacrificial gate layer (e.g., amorphous silicon, or the like) upon the sacrificial gate liner. The thickness of the sacrificial gate layer may be greater than the height of the one or more fins 125.

The sacrificial gate structure 144 may further be formed by subsequently forming a gate cap layer upon the sacrificial gate layer. The gate cap layer may be formed by depositing a mask material, such as a hard mask material. The gate cap layer may be composed of one or more layers masking materials to protect the sacrificial gate layer and/or other underlying materials during subsequent processing of device 100. The gate cap layer can be formed of known gate mask materials such as silicon nitride, silicon oxide, combinations thereof, or the like.

The gate cap layer, sacrificial gate layer, and sacrificial gate liner may be patterned using conventional lithography and etch process to remove undesired portions and retain desired portion(s), respectively. The retained desired portion(s) of the gate cap layer, sacrificial gate layer, and sacrificial gate liner may form the sacrificial gate liner (not shown), the sacrificial gate 140, and the sacrificial gate cap 142, respectively, of each of the one or more sacrificial gate structures 144.

Each sacrificial gate structure 144 can be formed on targeted regions or areas of semiconductor device 100 to define the length of one or more transistors, and to provide sacrificial material for yielding targeted transistor structure(s) in subsequent processing. According to an example, each sacrificial gate structure 144 can have a height of between approximately 50 nm and approximately 200 nm, and a length of between approximately nm and approximately 200 nm.

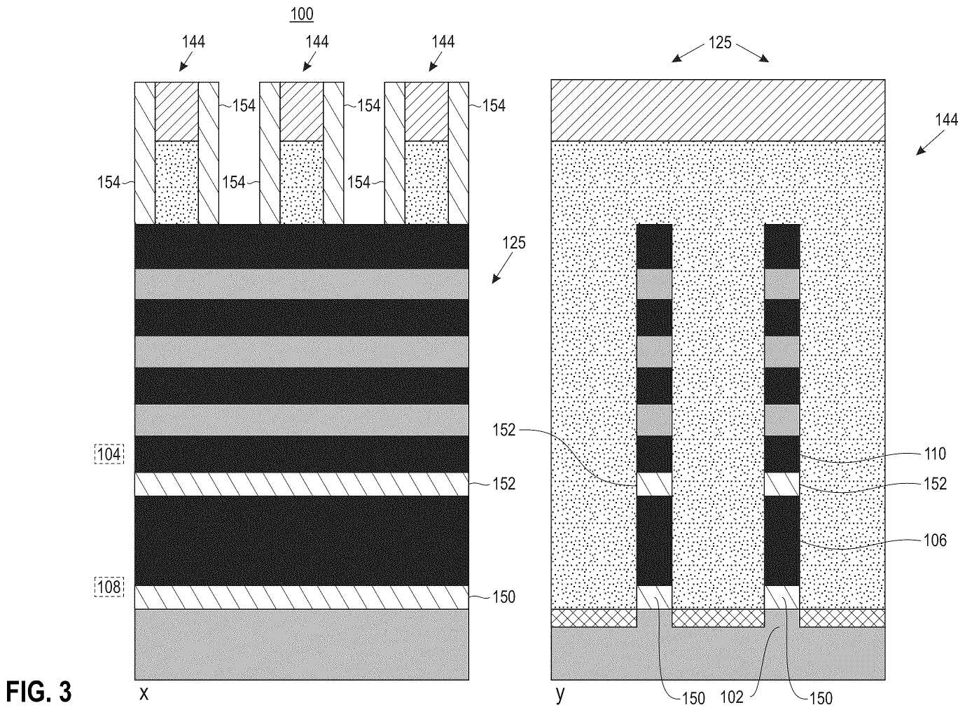

FIG. 3 depicts cross-sectional views of stacked semiconductor device 100 shown after exemplary fabrication operation(s), in accordance with one or more embodiments. In the depicted fabrication stage, as shown in block 406 of method 400 of fabricating semiconductor device 100 of FIG. 15, bottom sacrificial portion 104 and top sacrificial portion 108 are selectively removed.

In place of the removed bottom sacrificial portion 104, as shown in block 408 of method 400 of fabricating semiconductor device 100 of FIG. 15, a lower FinFET bottom dielectric isolation (BDI) region 150 may be formed between substrate 102 and channel fin 106 within each fin 125 and in place of the removed top sacrificial portion 108 (shown in FIG. 1), an upper middle dielectric isolation (MDI) region 152 may be formed between channel fin 106 and sacrificial nanolayer portion 110 within each fin 125. For clarity, the lower FinFET BDI region 150 and the upper MDI region 152 may be referred herein collectively as a dual dielectric isolation region or structure.

Further in the depicted fabrication stage, as shown in block 408 of method 400 of fabricating semiconductor device 100 of FIG. 15, a gate spacer 154 is formed around each of the one or more sacrificial gate structures 144. Each gate spacer 154 may further be formed upon a portion of the sidewalls of the one or more fins 125, and upon the top surface of a portion of the STI regions 130.

Bottom sacrificial portion 104 and top sacrificial portion 108 (shown in FIG. 1) may be selectively removed and may resultantly form an associated BDI cavity between substrate 102 and channel fin 106 and between channel fin 106 and sacrificial nanolayer portion 110, respectively.

FinFET BDI regions 150, 152 and gate spacers 154 may be simultaneously formed by a conformal deposition of a dielectric material, such as silicon nitride, SiBCN, SiNC, SiN, SiCO, SiNOC, or a combination thereof, or the like, within the BDI cavities and upon STI regions 130 and around each of the one or more sacrificial gate structures 144. Undesired portion(s) of the dielectric material may be removed by etching or other subtractive material removal process. Desired portion(s) of the dielectric material may be retained within the BDI cavities and may form FinFET BDI regions 150, 152. Further additional desired portion(s) of the dielectric material may be retained upon the top surface of STI regions 130 adjacent to and upon the sidewalls of the sacrificial gate structure 144 and around the one or more fins 125.

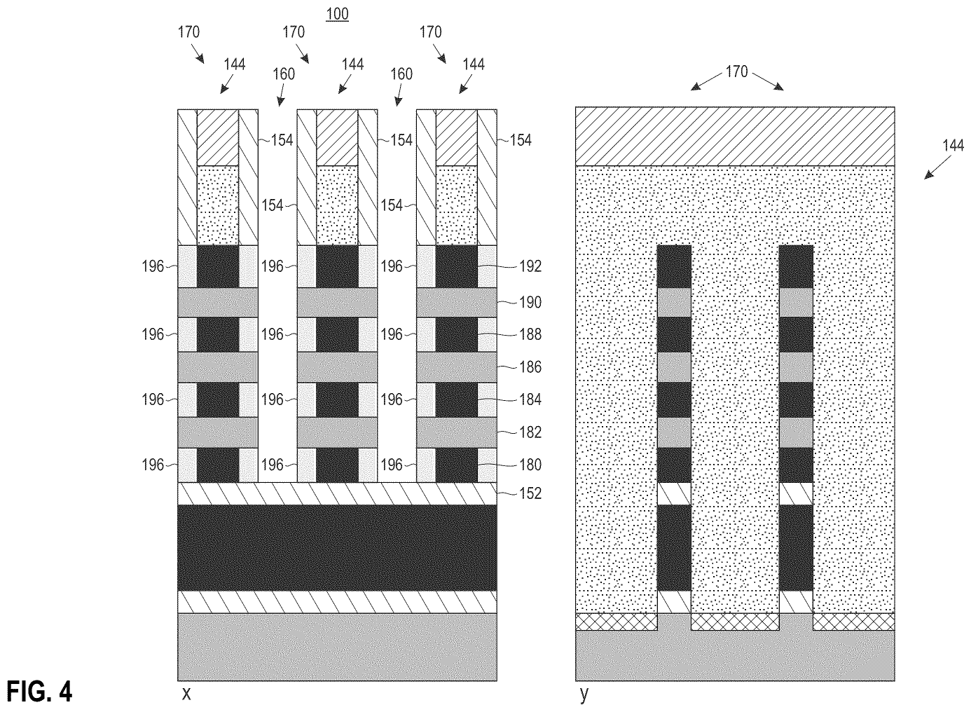

FIG. 4 depicts cross-sectional views of stacked semiconductor device 100 shown after exemplary fabrication operation(s), in accordance with one or more embodiments. In the depicted fabrication stage, as shown in block 410 of method 400 of fabricating semiconductor device 100 of FIG. 15, one or more source/drain (S/D) recesses 160 and one or more nanostructure stacks 170 are formed.

The one or more S/D recesses 160 and the one or more nanostructure stacks 170 may be formed by recessing or otherwise removing at least one respective portion of the one or more fins 125 that are not protected by sacrificial gate structure 144 and/or gate spacer 154. For example, unprotected and/or undesired portions of each fin 125 may be etched or otherwise removed. The etch may utilize the top surface of MDI 152 as an etch stop. The retained one or more portions of each fin 125 may effectively form one or more nanostructure stacks 170.

At the present fabrication operation stage of forming the one or more S/D recesses 160 resulting in the one or more nanostructure stacks 170, nanostructure stack 170 may include a sacrificial nanolayer portion 180 formed from the sacrificial nanolayer portion 110, a nanostructure channel 182 formed from nanostructure channel 112, a sacrificial nanolayer portion 184 formed from the sacrificial nanolayer portion 114, a nanostructure channel 186 formed from nanostructure channel 116, a sacrificial nanolayer portion 188 formed from the sacrificial nanolayer portion 118, a nanostructure channel 190 formed from nanostructure channel 120, and a sacrificial nanolayer portion 192 formed from the sacrificial nanolayer portion 122.

As shown in block 412 of method 400 of fabricating semiconductor device 100 of FIG. 15, the one or more nanostructure stacks 170 may be further modified or fabricated by selectively recessing the width or otherwise laterally indenting the sacrificial nanolayer portions 180, 184, 188, 192, etc. This lateral recessing of sacrificial nanolayer portions 180, 184, 188, 192 can be provided, e.g., vapor-phase process which leaves other structures (e.g., substrate 102, MDI 152, gate spacer 154, nanostructure channels 182, 186, 190, etc.) substantially intact.

As shown in block 412 of method 400 of fabricating semiconductor device 100 of FIG. 15, inner spacers 196 may be formed within the indentations or laterally recess of the sacrificial nanolayer portions 180, 184, 188, 192. Inner spacers 196 may be formed by depositing an electrically insulative material, such as a dielectric, to pinch off the previously formed recesses to yield an inner spacer 196 positioned therewithin, (e.g., above and below each nanostructure channel 182, 186, 190 within the nanosheet stack 170). For example, an inner spacer 196 can be formed upon the sidewall of sacrificial nanolayer portion 180 and between MDI 152 and nanostructure channel 182, an inner spacer 196 can be formed upon the sidewall of sacrificial nanolayer portion 184 and between nanostructure channel 182 and nanostructure channel 186, an inner spacer 196 can be formed upon the sidewall of sacrificial nanolayer portion 188 and between nanostructure channel 186 and nanostructure channel 190, and an inner spacer 196 can be formed upon the sidewall of sacrificial nanolayer portion 192 and between nanostructure channel 190 and gate spacer 154. At the present stage of fabrication of formation of spacers 196, nanostructure stack 170 may further include spacers 196.

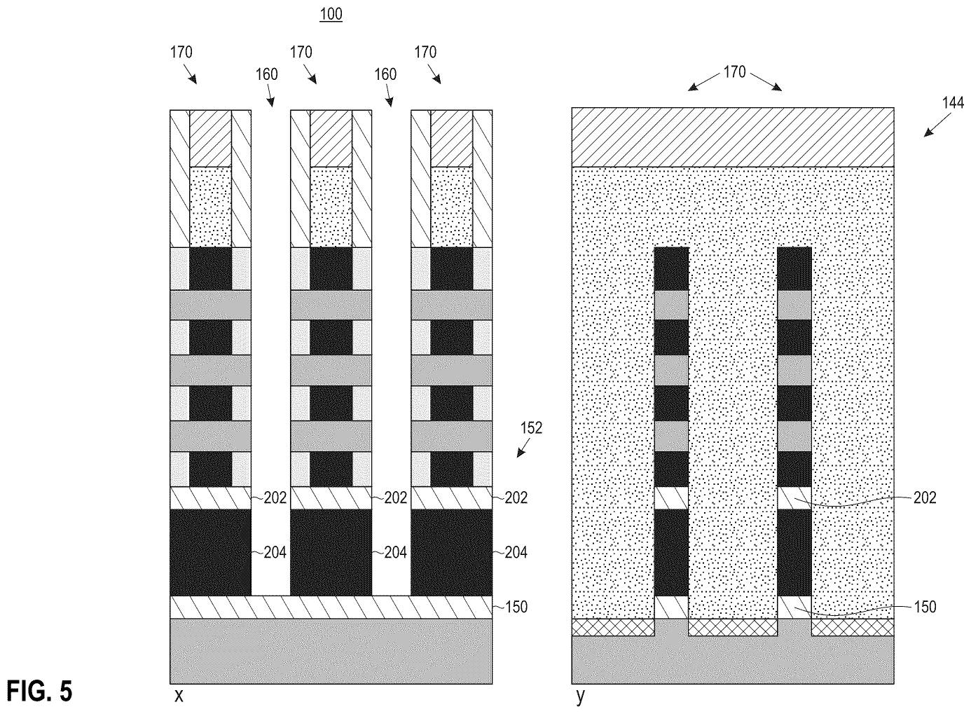

FIG. 5 depicts cross-sectional views of stacked semiconductor device 100 shown after exemplary fabrication operation(s), in accordance with one or more embodiments. In the depicted fabrication stage, the one or more S/D recesses 160 are enlarged.

The one or more S/D recesses 160 may be downwardly enlarged by further recessing or otherwise further removing at least one respective portion of MDI 152 and at least one respective portion of channel fin 106. For example, exposed portion(s) of MDI 152, by the one or more S/D recesses 160, may be etched or otherwise removed thereby exposing portion(s) channel fin 106. Subsequently, such exposed portion(s) channel fin 106 may be further etched or otherwise removed. The one or sequential etches to remove exposed portions of MDI 152 and underlying portion(s) channel fin 106 may utilize the top surface of FinFET BDI region 150 as an etch stop. The retained one or more FinFET BDI regions 152 may effectively form one or more FinFET BDI regions 202. The retained one or more regions of channel fin 106 may effectively form one or more fin channels 204. For clarity, multiple fin channels 204, which may be formed from SiGe, may be resultingly formed upon the same FinFET BDI region 150, as depicted.

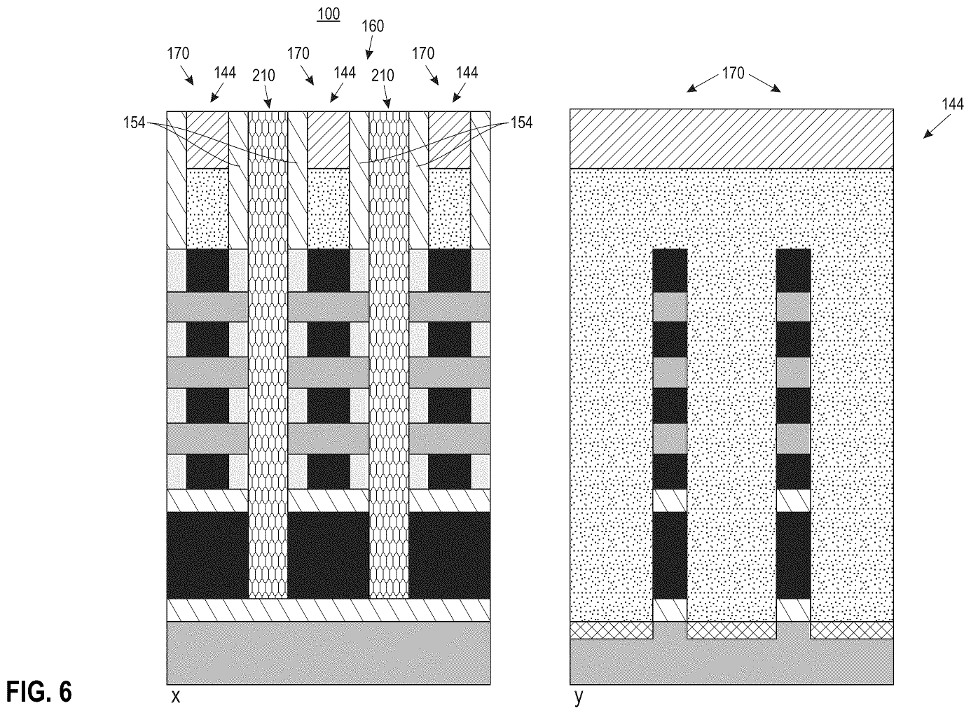

FIG. 6 depicts cross-sectional views of stacked semiconductor device 100 shown after exemplary fabrication operation(s), in accordance with one or more embodiments. In the depicted fabrication stage, as shown in block 414 of method 400 of fabricating semiconductor device 100 of FIG. 15, a S/D region 210 is formed in the one or more S/D recesses 160, respectively.

S/D region 210 may be formed by epitaxially growing a source/drain epitaxial region within S/D recess 160, e.g., from exposed inner sidewalls within S/D recess 160. In some embodiments, the S/D region 210 is formed by in-situ doped epitaxial growth. In some embodiments, epitaxial growth and/or deposition processes may be selective to forming on semiconductor surfaces, and may not deposit material on dielectric surfaces, such as silicon dioxide or silicon nitride surfaces. In some embodiments, the S/D region 210 epitaxial growth may overgrow above the upper surface of semiconductor device 100. Subsequently, the S/D region 210 may be planarized to the upper surface of semiconductor device 100.

Suitable n-type dopants include but are not limited to phosphorous (P), and suitable p-type dopants include but are not limited to boron (B). The use of an in-situ doping process is merely an example. For instance, one may instead employ an ex-situ process to introduce dopants into the source and drains. Other doping techniques can be used to incorporate dopants in the bottom source/drain region. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In preferred embodiments, the S/D epitaxial growth conditions that promote in-situ Boron doped SiGe for p-type transistor and phosphorus or arsenic doped silicon or Si:C for n-type transistors. The doping concentration in S/D region 210 can be in the range of 1×10¹⁹ cm⁻³ to 2×10²¹ cm⁻³, or preferably between 2×10²⁰ cm⁻³ to 7×10₂₀ cm⁻³.

In a particular embodiment, S/D region 210 is formed as an p-type S/D region and doped with p-type dopants.

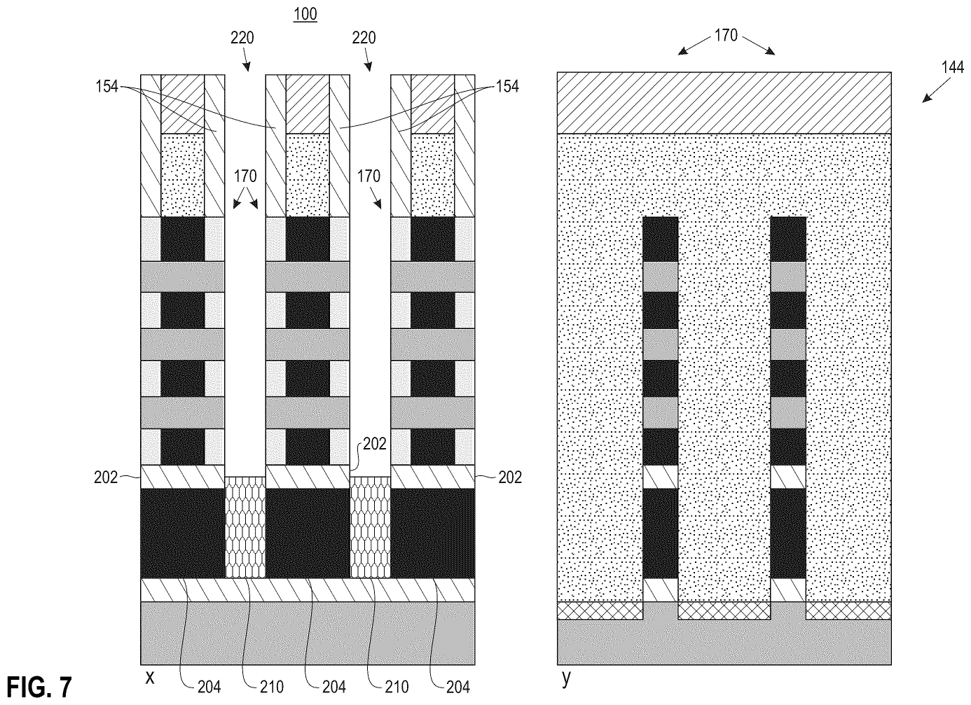

FIG. 7 depicts cross-sectional views of stacked semiconductor device 100 shown after exemplary fabrication operation(s), in accordance with one or more embodiments. In the depicted fabrication stage, one or more S/D recesses 220 are formed by partially recessing the one or more S/D regions 210.

The one or more S/D recesses 220 may be formed by partially recessing or otherwise removing an upper portion of the one or more S/D regions 210, respectively. For example, the upper portion of the one or more S/D regions 210 may be etched or otherwise removed. The etch may be timed or otherwise controlled to stop the removal of the one or more S/D regions 210 such that the top surface of the remaining one or more S/D regions 210 is coplanar with either, or between, the upper surface or/and bottom surface of FinFET BDI region 202.

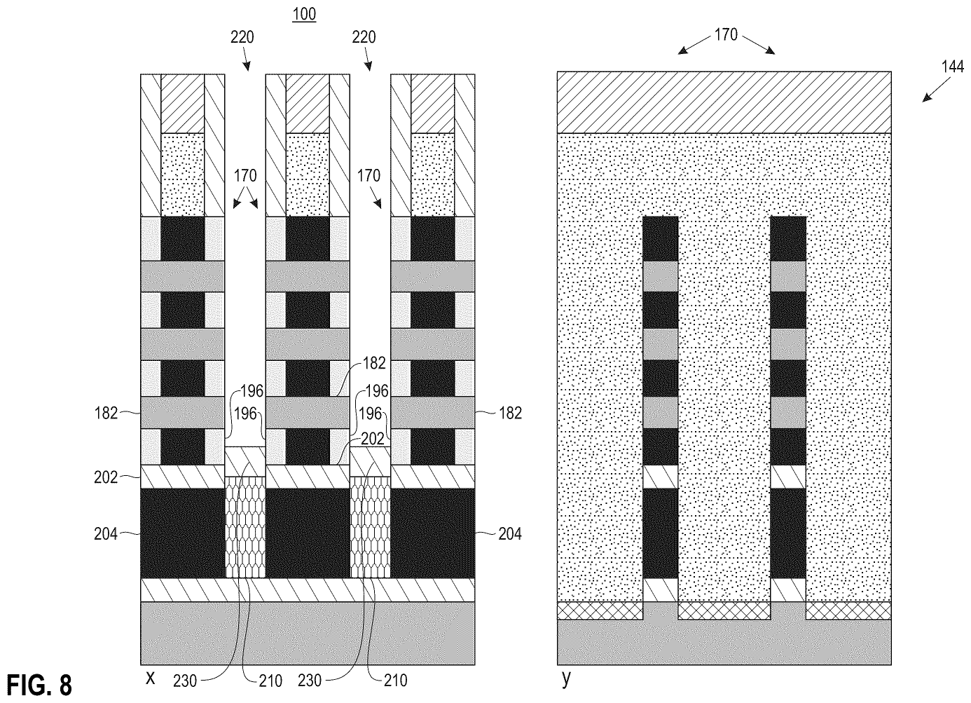

FIG. 8 depicts cross-sectional views of stacked semiconductor device 100 shown after exemplary fabrication operation(s), in accordance with one or more embodiments. In the depicted fabrication stage, as shown in block 416 of method 400 of fabricating semiconductor device 100 of FIG. 15, a S/D cap 230 is formed on the one or more S/D regions 210, respectively.

S/D cap 230 may be formed by depositing a dielectric material, such as silicon nitride, SiBCN, SiNC, SiN, SiCO, SiNOC, or a combination thereof, or the like, within a bottom or lower portion of the one or more S/D recesses 220 and upon S/D region 210. In an embodiment, S/D cap 230 may be formed to a thickness and subsequently etched back such that the top surface of S/D cap 230 is between a top surface of FinFET BDI region 202 and a bottom surface of nanostructure channel 182. Alternatively, S/D cap 230 may be formed to a thickness such that the top surface of S/D cap 230 is between a top surface of FinFET BDI region 202 and a bottom surface of nanostructure channel 182.

S/D cap 230 may be formed upon S/D region 210, upon a sidewall of FinFET BDI regions 202 that are associated with different and neighboring nanostructure stacks 170, and upon a sidewall of spacers 196 that are associated with different and neighboring nanostructure stacks 170. S/D cap 230 may also be referred to herein as a S/D insulator.

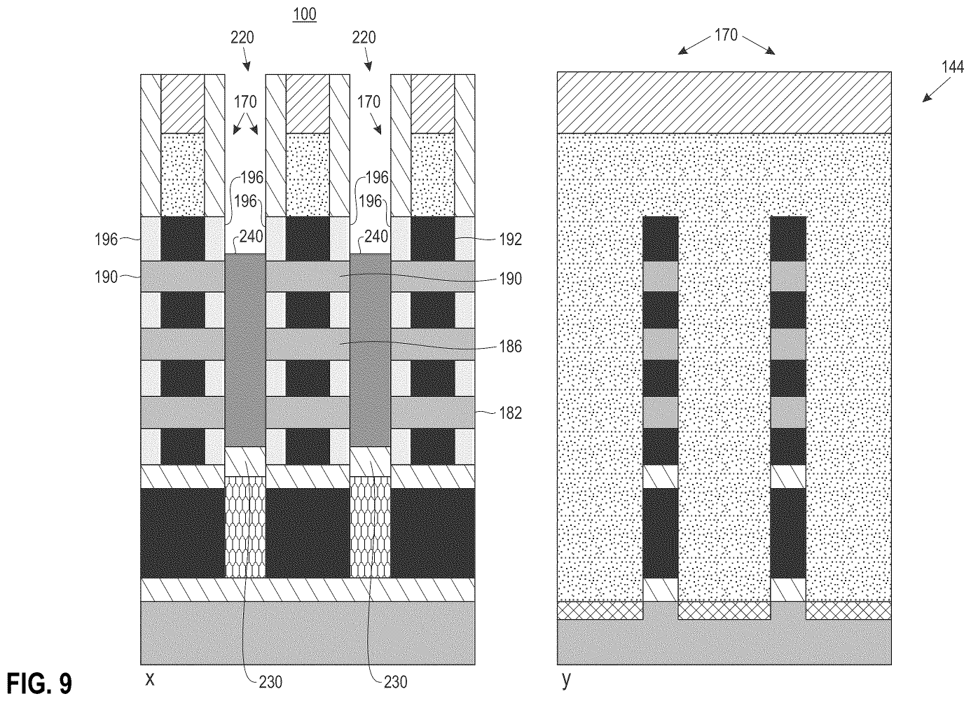

FIG. 9 depicts cross-sectional views of stacked semiconductor device 100 shown after exemplary fabrication operation(s), in accordance with one or more embodiments. In the depicted fabrication stage, as shown in block 418 of method 400 of fabricating semiconductor device 100 of FIG. 15, a S/D region 240 is formed in the one or more S/D recesses 220, respectively.

S/D region 240 may be formed by epitaxially growing a source/drain epitaxial region within S/D recess 220, e.g., from exposed inner sidewalls within S/D recess 220. For example, S/D region 240 may be epitaxially grown from the exposed nanostructure channel 182, 186, 190 sidewalls, respectively. In some embodiments, the S/D region 240 is formed by in-situ doped epitaxial growth. In some embodiments, epitaxial growth and/or deposition processes may be selective to forming on semiconductor surfaces, and may not deposit material on dielectric surfaces, such as silicon dioxide or silicon nitride surfaces.

Suitable n-type dopants include but are not limited to phosphorous (P), and suitable p-type dopants include but are not limited to boron (B). The use of an in-situ doping process is merely an example. For instance, one may instead employ an ex-situ process to introduce dopants into the source and drains. Other doping techniques can be used to incorporate dopants in the bottom source/drain region. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In preferred embodiments, the S/D epitaxial growth conditions that promote in-situ boron doped SiGe for p-type transistor and phosphorus or arsenic doped silicon or Si:C for n-type transistors. The doping concentration in S/D region 240 can be in the range of 1×10¹⁹ cm⁻³ to 2×10²¹ cm⁻³, or preferably between 2×10²⁰ cm⁻³ to 7×10²⁰ cm⁻³.

In a particular embodiment, S/D region 240 is formed as an n-type S/D region and doped with n-type dopants.

S/D region 240 may be formed within S/D recess 220 upon the top surface of S/D cap 230, upon sidewalls of spacers 196 that are associated with different and neighboring nanostructure stacks 170, upon sidewalls of nanostructure channel 182, 186, 190 that are associated with different and neighboring nanostructure stacks 170. S/D region 240 may be formed such that a top surface of S/D region 240 is coplanar with either, or between, a top surface of nanostructure channel 190 or/and a top surface of sacrificial nanolayer portion 192.

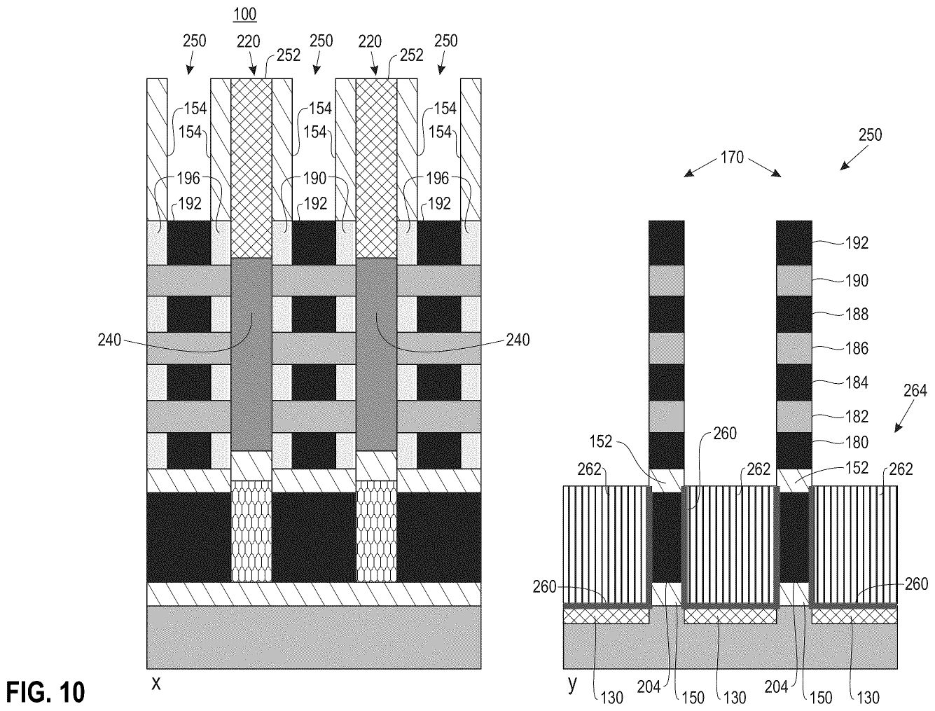

FIG. 10 depicts cross-sectional views of stacked semiconductor device 100 shown after exemplary fabrication operation(s), in accordance with one or more embodiments. In the depicted fabrication stage, as shown in block 420 of method 400 of fabricating semiconductor device 100 of FIG. 15, a gate opening 250 is formed and a lower replacement gate structure 264 is formed.

Gate opening 250 may be formed by removing sacrificial gate structure 144 and, as depicted in the Y cross-sectional view, may expose at least respective sections of the upper surface of STI regions 130, respective sidewall surface sections of fin channel 204, respective sidewall surface sections of MDI 152, respective sidewall surface sections of sacrificial nanolayer portions 180, 184, and 188, respective sidewall surface sections of nanolayer channels 182, 186, and 190, and respective sidewall and top surface sections of sacrificial nanolayer portion 192.

Lower replacement gate structure 264 can comprise a gate dielectric 260 and gate conductor 262. Gate dielectric 260 can comprise any suitable dielectric material, including but not limited to silicon oxide, silicon nitride, silicon oxynitride, high-k materials, or any combination of these materials. Examples of high-k materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k material may further include dopants such as lanthanum, aluminum, magnesium. The gate dielectric material can be formed by any suitable deposition process or the like. In some embodiments, the gate dielectric 260 has a thickness ranging from 1 nm to 5 nm, although less thickness and greater thickness are also conceived.

Gate conductor 262 can comprise any suitable conducting material, including but not limited to, doped polycrystalline or amorphous silicon, germanium, silicon germanium, a metal (e.g., tungsten (W), titanium (Ti), tantalum (Ta), ruthenium (Ru), hafnium (Hf), zirconium (Zr), cobalt (Co), nickel (Ni), copper (Cu), aluminum (Al), platinum (Pt), tin (Sn), silver (Ag), gold (Au), a conducting metallic compound material (e.g., tantalum nitride (TaN), titanium nitride (TiN), tantalum carbide (TaC), titanium carbide (TiC), titanium aluminum carbide (TiAlC), tungsten silicide (WSi), tungsten nitride (WN), ruthenium oxide (RuO2), cobalt silicide (CoSi), nickel silicide (NiSi)), transition metal aluminides (e.g. Ti3Al, ZrAl), TaC, TaMgC, carbon nanotube, conductive carbon, graphene, or any suitable combination of these materials.

Gate conductor 262 may further comprise dopants that are incorporated during or after deposition. In some embodiments, the gate conductor 262 may further comprise a workfunction setting layer (not shown) between the gate dielectric 260 and gate conductor 262. The workfunction setting layer can be a workfunction metal (WFM). WFM can be any suitable material, including but not limited a nitride, including but not limited to titanium nitride (TiN), titanium aluminum nitride (TiAlN), hafnium nitride (HfN), hafnium silicon nitride (HfSiN), tantalum nitride (TaN), tantalum silicon nitride (TaSiN), tungsten nitride (WN), molybdenum nitride (MoN), niobium nitride (NbN); a carbide, including but not limited to titanium carbide (TiC) titanium aluminum carbide (TiAlC), tantalum carbide (TaC), hafnium carbide (HfC), and combinations thereof. In some embodiments, a conductive material or a combination of multiple conductive materials can serve as both gate conductor and WFM. The gate conductor and WFM can be formed by any suitable process or any suitable combination of multiple processes, including but not limited to, atomic layer deposition (ALD), chemical vapor deposition (CVD), physical vapor deposition (PVD), sputtering, plating, evaporation, ion beam deposition, electron beam deposition, laser assisted deposition, chemical solution deposition, etc.

Lower replacement gate structure 264 may be formed by initially forming a gate dielectric layer upon substrate STI regions 130 and upon and around fins 125 within gate opening 250. For instance, the gate dielectric layer may be deposited upon the upper surface of STI regions 130, sidewalls of fin channel 204, sidewalls of MDI 152, sidewalls of sacrificial nanolayer portion 180, sidewalls of nanostructure channel 182, sidewalls of sacrificial nanolayer portion 184, sidewalls of nanostructure channel 186, sidewalls of sacrificial nanolayer portion 188, sidewalls of nanostructure channel 190, and sidewalls and upper surface of sacrificial nanolayer portion 192. Lower replacement gate structure 264 may further be formed by subsequently forming a gate conductor layer upon the gate dielectric layer.

The gate conductor layer and gate dielectric layer may be patterned using conventional lithography and etch process to remove undesired portions and retain desired portion(s), respectively. The retained desired portion(s) of the gate conductor layer and gate dielectric layer may form the gate dielectric 260 and gate conductor 262 of the lower replacement gate structure 264. As depicted in the Y cross-section, the lower replacement gate structure 264 may include a portion upon STI region 130 and upon an outside sidewall of a first nanostructure stack 170, may include another portion upon STI region 130 and upon both the inside sidewall of first nanostructure stack 170 and an inside sidewall of the second neighboring nanostructure stack 170, and may include a portion on STI region 130 and upon an outside sidewall of the second nanostructure stack 170.

The etch process, or another subtractive removal technique, may remove undesired portions of lower replacement gate structure 264, such that a top surface of lower replacement gate structure 264 is coplanar with, or between, the lower surface of MDI 152 and the top surface of MDI 152.

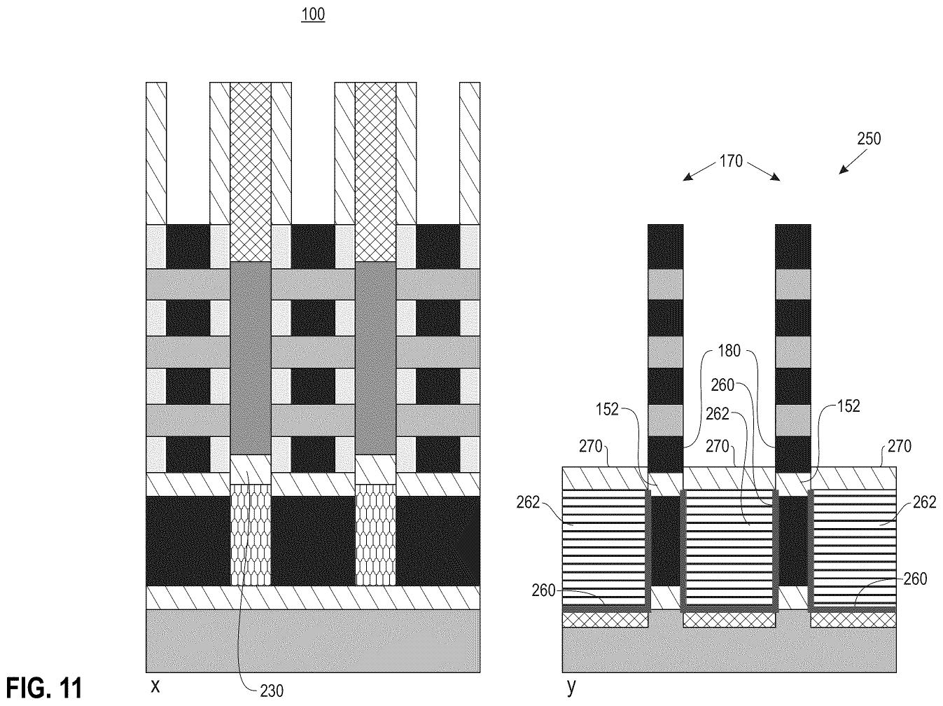

FIG. 11 depicts cross-sectional views of stacked semiconductor device 100 shown after exemplary fabrication operation(s), in accordance with one or more embodiments. In the depicted fabrication stage, as shown in block 422 of method 400 of fabricating semiconductor device 100 of FIG. 15, gate cap 270 is formed upon a top surface or top surfaces, and may become apart of, lower replacement gate structure 264 within gate opening 250.

The gate cap 270 may be formed by depositing a mask material, such as a hard mask material. The gate cap layer may be composed of one or more layers masking materials to protect the lower replacement gate structure 264. The gate cap layer can be formed of dielectric or other known gate mask materials such as silicon nitride, silicon oxide, combinations thereof, or the like.

Gate cap 270 may be formed to a thickness such that a top surface of gate cap 270 is coplanar with, or between, the upper surface of MDI 152, or the bottom surface of sacrificial nanolayer portion 180, and the top surface of sacrificial nanolayer portion 180. For example, a dielectric layer is formed and subsequently etched to remove undesired portions thereof, while the retain portions thereof form gate cap 270 within gate opening 250. In an implementation, gate cap 270 may be further formed to a thickness such that the top surface of gate cap 270 may be coplanar with a top surface of S/D cap 230. Gate cap 270 may also be referred to herein as gate insulator.

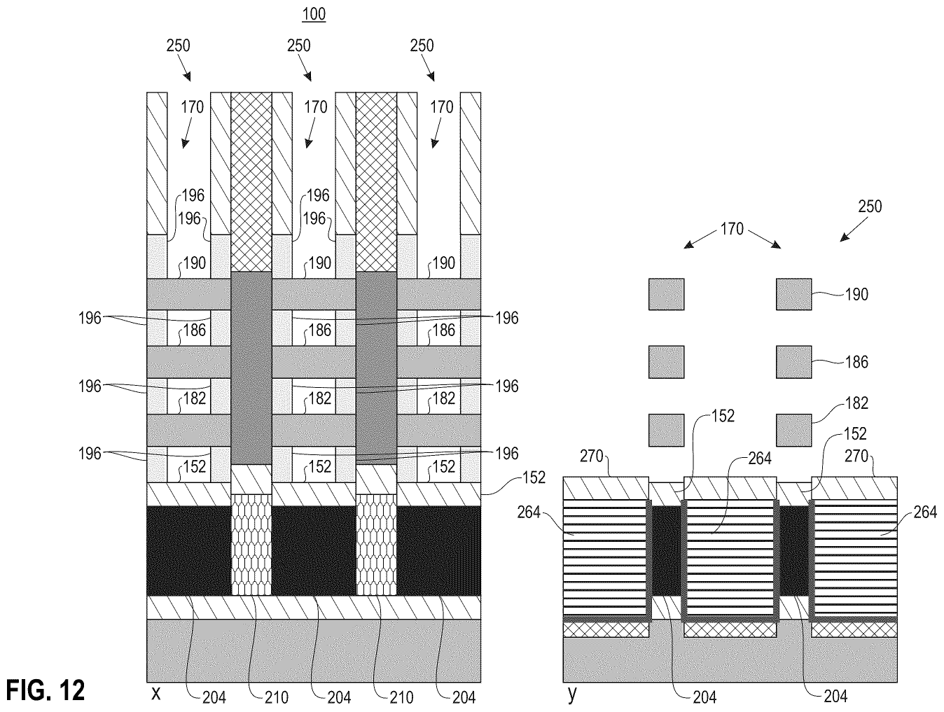

FIG. 12 depicts cross-sectional views of stacked semiconductor device 100 shown after exemplary fabrication operation(s), in accordance with one or more embodiments. In the depicted fabrication stage, as shown in block 424 of method 400 of fabricating semiconductor device 100 of FIG. 15, nanostructure stack 170 is modified by selectively removing the sacrificial nanolayer portions 180, 184, 188, and 192.

Various techniques may be utilized to process the nanostructure stack 170. For example, gate opening 250 may laterally, or otherwise, expose the nanostructure stack 170. Subsequently, the exposed sacrificial nanolayer portions 180, 184, 188, and 192 may be removed to laterally, or otherwise, expose the nanolayer channel 182, 186, and 190 within the nanostructure stack 170. As depicted in the X cross-section, the nanolayer channel 182, 186, and 190 may be exposed inside or within neighboring inner spacers 196 associated with neighboring nanostructure stacks 170.

The removal of sacrificial nanolayer portions 180 may create a trough, or step down, within the isolation or dielectric structure or layer that separates, or is between, the lower transistor (e.g., the fin channel(s) 204, lower replacement gate structure(s) 264, and S/D regions 210) and the upper transistor of the transistor stack. In other words, the upper surface of MDI 152 may be lower than the upper surface of gate cap 270, as depicted.

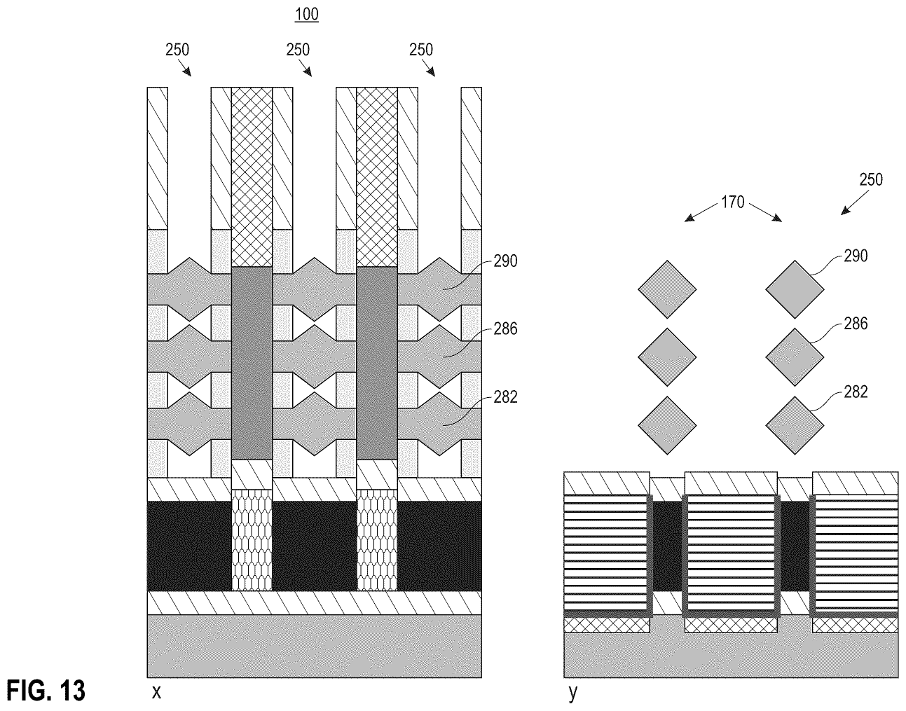

FIG. 13 depicts cross-sectional views of stacked semiconductor device 100 shown after exemplary fabrication operation(s), in accordance with one or more embodiments. In the depicted fabrication stage, as shown in block 426 of method 400 of fabricating semiconductor device 100 of FIG. 15, nanostructure stack 170 is modified by trimming the nanolayer channel 182, 186, and 190 and forming diamond-shaped nano channels 282, 286, and 290 from nanolayer channel 182, 186, and 190.

The nanolayer channel 182, 186, and 190 may be trimmed by for example an etch or other selective removal process. The nanolayer channel 182, 186, and 190 may be trimmed be trimmed to increase the vertical space between adjacent nanolayer channel 182, 186, and 190 before growing the diamond to prevent the diamond tips from adjacent nanowire to merge in the vertical direction. The trimming can be done either be using a vapor phase etch process or controlled etch cycles.

Diamond-shaped nano channels 282, 286, and 290 may be formed by epitaxially growing one layer and then the next until the desired thickness or shape of growth has been achieved. In a particular implementation, as is exemplarily depicted, diamond-shaped nano channels 282, 286, and 290 may be formed by epitaxially growing Si from associated one or more surface(s) of nanolayer channel 182, 186, and 190.

In a particular implementation, as is exemplarily depicted, diamond-shaped nano channels 282, 286, and 290 have angled sidewalls generally in a rhombus, diamond-shaped, or similar applicable shape. For example, epitaxial growth of diamond-shaped nano channels 282, 286, and 290 from applicable surfaces of nanolayer channels 182, 186, and 190 forms a diamond-shaped like structure. The outside or perimeter surfaces of this diamond-shaped like structure generally have a (111) orientated crystalline surface. In certain implementations, the (111) orientated crystalline surface(s) may be conduction surface(s) for one or more NFETs. Such 111) orientated crystalline surface(s) provides improved electron mobility which are carriers for N-type devices.

FIG. 14 depicts cross-sectional views of stacked semiconductor device 100 shown after exemplary fabrication operation(s), in accordance with one or more embodiments. In the depicted fabrication stage, as shown in block 428 of method 400 of fabricating semiconductor device 100 of FIG. 15, an upper replacement gate structure 312 is formed within gate opening 250 around diamond-shaped nano channels 282, 286, and 290.

Upper replacement gate structure 312 can comprise a gate dielectric 302 and gate conductor 310. Gate dielectric 302 can comprise any suitable dielectric material, including but not limited to silicon oxide, silicon nitride, silicon oxynitride, high-k materials, or any combination of these materials. The gate dielectric 302 can be formed by any suitable deposition process or the like. In some embodiments, the gate dielectric 302 has a thickness ranging from 1 nm to 5 nm, although less thickness and greater thickness are also conceived.

Gate conductor 310 can comprise any suitable conducting material, including but not limited to, doped polycrystalline or amorphous silicon, germanium, silicon germanium, a metal (e.g., tungsten (W), titanium (Ti), tantalum (Ta), ruthenium (Ru), hafnium (Hf), zirconium (Zr), cobalt (Co), nickel (Ni), copper (Cu), aluminum (Al), platinum (Pt), tin (Sn), silver (Ag), gold (Au), a conducting metallic compound material (e.g., tantalum nitride (TaN), titanium nitride (TiN), tantalum carbide (TaC), titanium carbide (TiC), titanium aluminum carbide (TiAlC), tungsten silicide (WSi), tungsten nitride (WN), ruthenium oxide (RuO2), cobalt silicide (CoSi), nickel silicide (NiSi)), transition metal aluminides (e.g. Ti3Al, ZrAl), TaC, TaMgC, carbon nanotube, conductive carbon, graphene, or any suitable combination of these materials.

Gate conductor 310 may further comprise dopants that are incorporated during or after deposition. In some embodiments, the gate conductor 310 may further comprise a workfunction setting layer (not shown) between the gate dielectric 302 and gate conductor 310. The workfunction setting layer can be a workfunction metal (WFM). The gate conductor 310 and WFM can be formed by any suitable process or any suitable combination of multiple processes, including but not limited to, atomic layer deposition (ALD), chemical vapor deposition (CVD), physical vapor deposition (PVD), sputtering, plating, evaporation, ion beam deposition, electron beam deposition, laser assisted deposition, chemical solution deposition, etc.

Upper replacement gate structure 312 may be formed by initially forming the gate dielectric layer within gate opening 250 around the diamond-shaped like structures of diamond-shaped nano channels 282, 286, and 290, upon sidewalls of inner spacers 196, upon gate spacers 154, upon the top surface of MDI 152, and upon the top surface of gate cap 270. Upper replacement gate structure 312 may further be formed by subsequently forming a gate conductor layer upon the gate dielectric layer. For clarity, upper replacement gate structure 312 may be a wrap around gate, since the gate conductor 310 wraps around the diamond-shaped nano channels 282, 286, and 290, as is depicted in the Y cross-section.

The gate conductor layer and gate dielectric layer may be patterned using conventional lithography and etch process to remove undesired portions and retain desired portion(s), respectively. The retained desired portion(s) of the gate conductor layer and gate dielectric layer may form the gate dielectric layer 302 and gate conductor 310 of the upper replacement gate structure 310. The etch process, or another subtractive removal technique, may remove undesired portions of upper replacement gate structure 312, such that a top surface of upper replacement gate structure 312 is coplanar with the top surface of semiconductor device 100.

In some implementations, gate conductor 310 can be recessed below the top surface of semiconductor device 100 and a dielectric gate cap (not shown) can be formed upon the recessed gate conductor 310.

For clarity, semiconductor device 100 may include stacked transistors. A lower transistor may be a p-type FinFET and an upper transistor vertically above the lower transistor may be a n-type nanostructure FET. The p-type FinFET may include a fin channel 204, formed of e.g., SiGe, with (110) orientated crystalline surface. End surfaces of the fin channel 204 may contact a respective S/D region 210. Side surfaces of the fin channel 204 may contact a respective lower replacement gate structure 264. The n-type nanostructure FET has e.g., Si diamond-shaped nano channels 282, 286, and 290. End surfaces of the diamond-shaped nano channels 282, 286, and 290 may contact a respective S/D region 240. An upper replacement gate structure 312 may wrap around and contact the diamond-shaped nano channels 282, 286, and 290. A dielectric or electrical isolation structure or material(s) (e.g., MDI 152, gate cap 270, gate dielectric 302, etc.) may separate the upper replacement gate structure 312 from the lower replacement gate structure 264.

In an implementation, gate dielectric 302 of the upper replacement gate structure 312 may be a different dielectric material relative to the gate dielectric 260 of the lower replacement gate structure 264. Such optionality allows for independent optimization or selection of the gate dielectric 302 around the nano structure channels 282, 286, 290 in relation to the gate dielectric 260 that is upon the fin channel 204.

FIG. 15 depicts a flow diagram illustrating method 400 of fabricating semiconductor device 100, according to one or more embodiments of the present invention. The depicted fabrication operations of method 400 are illustrated and described above with reference to FIG. 1 through FIG. 14. Method 400 depicted herein is exemplary. There can be many variations to the diagram or operations described therein without departing from the spirit of the embodiments. For instance, the operations can be performed in a differing order, or operations can be added, deleted or modified. All of these variations are considered a part of the claimed embodiments.

The descriptions of the various embodiments of the present invention have been presented for purposes of illustration but are not intended to be exhaustive or limited to the embodiments described. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments described herein.

What is claimed is:

1. A stacked semiconductor device comprising:
a lower transistor comprising a fin channel, a lower source/drain (S/D) region that contacts an end surface of the fin channel, and a lower gate structure that contacts a sidewall of the fin channel; and
an upper transistor stacked vertically above the lower transistor, the upper transistor comprising a diamond-shaped nano channel, an upper S/D region that contacts an end surface of the diamond-shaped nano channel, and an upper gate structure that wraps around and contacts the diamond-shaped nano channel.

2. The stacked semiconductor device of claim 1, wherein the lower transistor is a p-type FinFET and wherein the upper transistor is a n-type nanostructure FET.

3. The stacked semiconductor device of claim 2, wherein the fin channel is a Silicon Germanium (SiGe) fin channel and wherein the diamond-shaped nano channel is a Silicon diamond-shaped nano channel.

4. The stacked semiconductor device of claim 3, further comprising:
a dual dielectric isolation region comprising a lower bottom-dielectric isolation (BDI) layer and a middle-dielectric isolation (MDI) layer.

5. The stacked semiconductor device of claim 4, wherein the MDI layer is directly upon a top surface of the fin channel.

6. The stacked semiconductor device of claim 5, further comprising a gate insulator between the lower gate structure and the upper gate structure.

7. The stacked semiconductor device of claim 6, further comprising a S/D insulator between the lower S/D region and the upper S/D region.

8. The stacked semiconductor device of claim 7, wherein the lower S/D region is directly between the lower BDI layer and the S/D insulator.

9. The stacked semiconductor device of claim 8, wherein the fin channel comprises a (110) crystalline planar side surface and the diamond-shaped nano channel comprises a (111) crystalline planar diamond-shaped surface.

10. A stacked semiconductor device comprising:
a lower transistor comprising a fin channel, a lower source that contacts an end surface of the fin channel, a lower drain that contacts a distal end surface of the fin channel, and lower gate that contacts a sidewall of the fin channel; and
an upper transistor stacked vertically above the lower transistor, the upper transistor comprising a diamond-shaped nano channel, an upper source that contacts an end surface of the diamond-shaped nano channel, an upper drain that contacts a distal end surface of the diamond-shaped nano channel, and an upper gate that wraps around and contacts a perimeter of the diamond-shaped nano channel.

11. The stacked semiconductor device of claim 10, wherein the lower transistor is a p-type FinFET and wherein the upper transistor is a n-type nanostructure FET.

12. The stacked semiconductor device of claim 11, wherein the fin channel is a Silicon Germanium (SiGe) fin channel and wherein the diamond-shaped nano channel is a Silicon diamond-shaped nano channel.

13. The stacked semiconductor device of claim 12, further comprising:
a dual dielectric isolation region comprising a lower bottom-dielectric isolation (BDI) layer and a middle-dielectric isolation (MDI) layer.

14. The stacked semiconductor device of claim 13, wherein the MDI layer is directly upon a top surface of the fin channel and wherein the lower BDI layer is directly between a bottom surface of the fin channel and a substrate.

15. The stacked semiconductor device of claim 14, further comprising a gate insulator between the lower gate structure and the upper gate structure.

16. The stacked semiconductor device of claim 15, further comprising a first source/drain (S/D) insulator between the lower drain and the upper source and a second S/D insulator between the lower source and the upper drain.

17. The stacked semiconductor device of claim 16, wherein the lower source and the lower drain are directly upon the lower BDI layer.

18. The stacked semiconductor device of claim 17, wherein the fin channel comprises a (110) crystalline planar side surface and the diamond-shaped nano channel comprises a (111) crystalline planar diamond-shaped surface.

19. A stacked semiconductor device fabrication method comprising:
forming a fin channel of a lower transistor;
forming a lower gate structure of the lower transistor upon a sidewall of the fin channel;
forming a diamond-shaped channel of an upper transistor that is vertically stacked above the lower transistor; and
forming an upper gate structure of the upper transistor upon and around the diamond-shaped channel.

20. The stacked semiconductor device fabrication method of claim 19, further comprising:
forming an electrical isolation structure upon the lower transistor and between the lower transistor and the upper transistor.
